(19) United States
(12) Patent Application Publication
(10) Pub. No.: US 2024/0329743 A1
(43) Pub. Date: Oct. 3, 2024

(54) DISPLAY DEVICE AND ELECTRONIC DEVICE

(71) Applicant: Taiyo Yuden Co., Ltd., Tokyo (JP)

(72) Inventors: Fumihisa ITO, TOKYO (JP); Yukihiro MATSUI, TOKYO (JP)

(21) Appl. No.: 18/580,398

(22) PCT Filed: Jun. 28, 2022
(86) PCT No.: PCT/JP2022/025696

§ 371 Date: Jan. 18, 2024

(30) Foreign Application Priority Data
Jul. 27, 2021 (JP) 2021-122228

(51) Int. Cl. G06F 3/01; G06F 3/044; H10N 30/20; H10N 39/00

(52) U.S. Cl. CPC G06F 3/016; H10N 30/20; H10N 39/00; G06F 3/044

(57) ABSTRACT

[Object]

To provide a display device and an electronic device each capable of implementing both a force feedback function and a tactile function and having high strength.

[Solving Means]

A display device according to the present invention includes a display panel, a touch panel, a spacer, a tactile panel, and a piezoelectric actuator. The touch panel is placed on the display panel and has a first principal surface on the display panel side and a second principal surface on the side opposite to the first principal surface. The tactile panel is placed on the spacer and has a third principal surface facing the second principal surface with a gap between the third and second principal surfaces and a fourth principal surface on the side opposite to the third principal surface. The piezoelectric actuator is placed on the third principal surface and causes vibration. When a first thickness is defined as the thickness from the second principal surface to the fourth principal surface and a second thickness is defined as the thickness from the second principal surface to the third principal surface, the first thickness is 0.5 to 1.5 mm, is equal to or larger than the thickness obtained by adding 0.3 mm to the second thickness, and is equal to or smaller than the thickness obtained by adding 1 mm to the second thickness.

### TECHNICAL FIELD

The present invention relates to a display device and an electronic device capable of tactile presentation.

### BACKGROUND ART

Some smartphones, car navigation systems, and other devices have a force feedback function that causes vibration when a touch panel is operated to notify that an input has been received. In recent years, in addition to vibration for notifications, there has been studied and developed tactile technology that uses variations in vibration to express the feel of displayed objects and to allow the operating position to be grasped.

Such tactile technology can be achieved by vibrating a piezoelectric actuator bonded to a tactile panel, at a frequency in the ultrasonic band. Vibration in the ultrasonic band forms standing waves on the tactile panel, and when the tactile panel is touched with a finger, for example, a tactile sensation can be obtained, and by changing the signal pattern supplied to the piezoelectric actuator, various senses of touch can be expressed. Therefore, in order to express a tactile sensation on the touch panel, this tactile panel is required separately.

Here, a display panel such as a liquid crystal display is equipped with a reinforced cover glass to protect the surface, and glass having a thickness of 0.2 to 1.0 mm is used to ensure strength. In addition, for example, PTL 1 discloses a liquid crystal display reinforcing structure in which the strength of the display panel is improved by providing an arch-shaped display panel in front of the liquid crystal display. Further, PTL 2 discloses a display panel device provided with a heat sink on the back surface of a liquid crystal display to have both a cooling function and an improved strength.

### CITATION LIST

### Patent Literature

### [PTL 1]

JP 2005-215087A

### [PTL 2]

JP 2006-53529A

### SUMMARY

### Technical Problem

Moreover, the tactile function by ultrasonic drive of a piezoelectric actuator can be achieved by placing the piezoelectric actuator at the edge of a tactile panel and generating standing waves over the entire surface of the panel. However, in order to provide a low-frequency drive force feedback function by use of a piezoelectric actuator, the piezoelectric actuator needs to be placed directly under the back of the tactile panel because low-frequency vibration will be attenuated in the middle of the panel and the piezoelectric actuator cannot function when the piezoelectric actuator is placed in the same position. Therefore, a tactile function based on ultrasonic drive and a force feedback function based on low frequency drive by use of a single piezoelectric actuator cannot be achieved.

In view of the above circumstances, an object of the present invention is to provide a display device and an electronic device that are capable of having both a force feedback function and a tactile function and that have high strength.

### Solution to Problem

In order to achieve the above object, a display device according to one embodiment of the present invention includes a display panel, a touch panel, a spacer, a tactile panel, and a piezoelectric actuator.

The touch panel is disposed on the display panel and has a first principal surface facing the display panel and a second principal surface on the side opposite to the first principal surface.

The spacer is disposed on the second principal surface.

The tactile panel is disposed on the spacer and has a third principal surface facing the second principal surface with a gap between the third and second principal surfaces and a fourth principal surface on the side opposite to the third principal surface.

The piezoelectric actuator is disposed on the third principal surface and generates vibration.

When the thickness from the second principal surface to the fourth principal surface is a first thickness and the thickness from the second principal surface to the third principal surface is a second thickness, the first thickness is 0.5 to 1.5 mm, is equal to or greater than the thickness obtained by adding 0.3 mm to the second thickness, and is equal to or less than the thickness obtained by adding 1 mm to the second thickness.

The abovementioned display device may be further provided with a drive unit that supplies the piezoelectric actuator with an ultrasonic drive signal that causes the piezoelectric actuator to generate vibration in an ultrasonic band and a low frequency drive signal that causes the piezoelectric actuator to generate vibration in a low frequency band.

The abovementioned spacer may include a material having an elastic modulus of 1.0×10⁶ to 6.0×10⁶ Pa.

The abovementioned second thickness may be 0.05 to 0.8 mm.

The abovementioned tactile panel may have a rectangular shape having a width of the long side that is 1 time to 2.5 times larger than the width of the short side.

The abovementioned tactile panel may include resin or glass.

In order to achieve the above object, an electronic device according to one embodiment of the present invention includes a display panel, a touch panel, a spacer, a tactile panel, a piezoelectric actuator.

The touch panel is disposed on the display panel and has a first principal surface facing the display panel and a second principal surface on the side opposite to the first principal surface.

The spacer is disposed on the second principal surface.

The tactile panel is disposed on the spacer and has a third principal surface facing the second principal surface with a gap between the third and second principal surfaces and a fourth principal surface on the side opposite to the third principal surface.

The piezoelectric actuator is disposed on the third principal surface and generates vibration.

When the thickness from the second principal surface to the fourth principal surface is a first thickness and the thickness from the second principal surface to the third principal surface is a second thickness, the first thickness is 0.5 to 1.5 mm, is equal to or greater than the thickness obtained by adding 0.3 mm to the second thickness, and is equal to or less than the thickness obtained by adding 1 mm to the second thickness.

### Advantageous Effect of Invention

As described above, according to the present invention, a display device and an electronic device that are capable of having both the force feedback function and the tactile function and that have high strength can be provided.

### BRIEF DESCRIPTION OF DRAWINGS

FIG. 1 is a side view of a display device according to an embodiment of the present invention.

FIG. 2 is a plan view of the front side of the display device.

FIG. 3 is a plan view of the back side of the display device.

FIG. 4 is a cross-sectional view of the display device.

FIG. 5 is a schematic diagram illustrating an exploded view of the display device.

FIG. 6 is a cross-sectional view of a piezoelectric actuator included in the display device.

FIG. 7 is a schematic diagram illustrating the operation of the display device.

FIG. 8 is a schematic diagram illustrating the size of the display device.

FIG. 9 is a schematic diagram illustrating the size of the display device.

FIG. 10 is a graph illustrating the relation between a first thickness and a second thickness of the display device.

FIG. 11 is a schematic diagram of a display device according to a comparative example.

FIG. 12 is a schematic diagram of a display device according to a modification example of the present invention.

### DESCRIPTION OF EMBODIMENT

The display device according to the present embodiment will be described below.

### [Display Device Configuration]

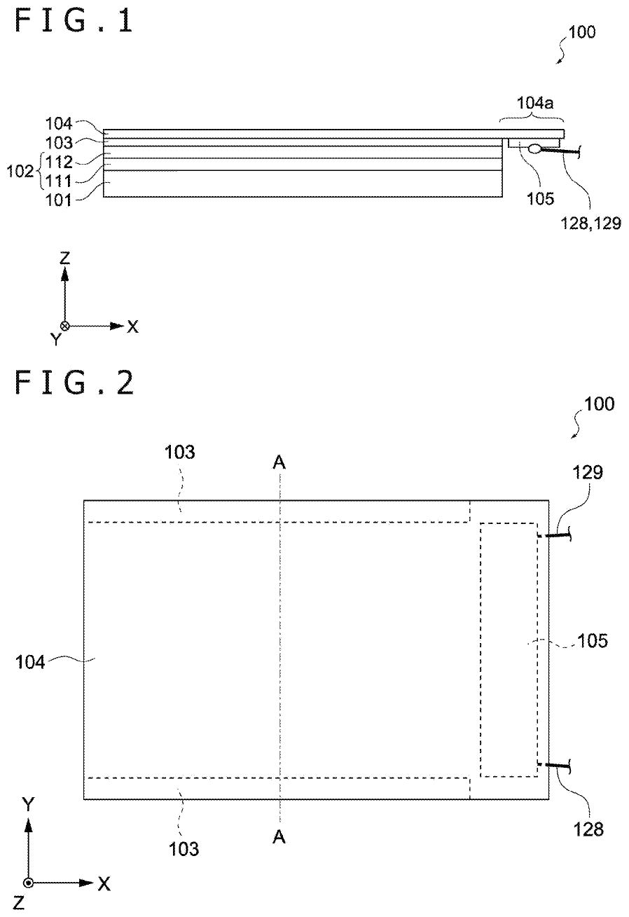

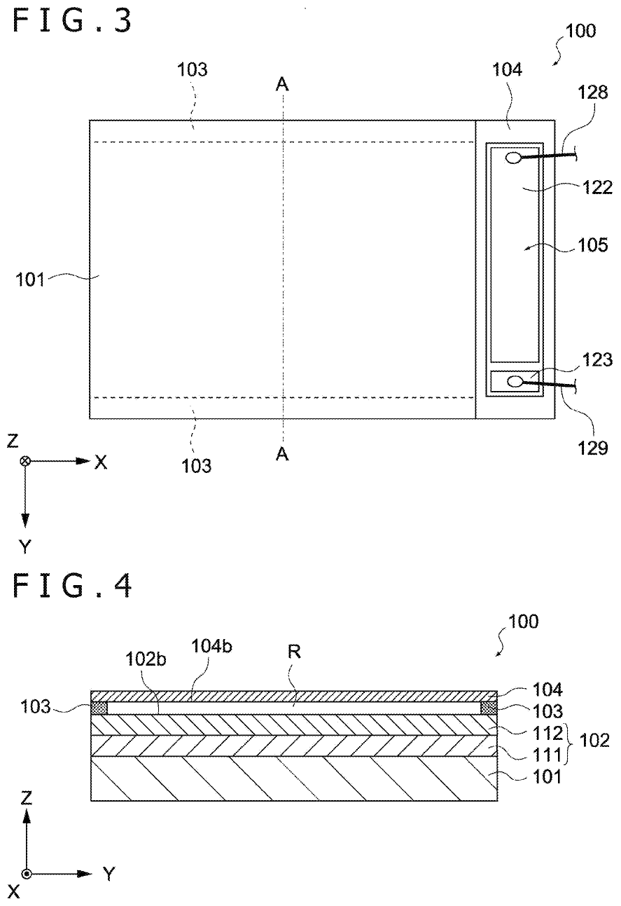

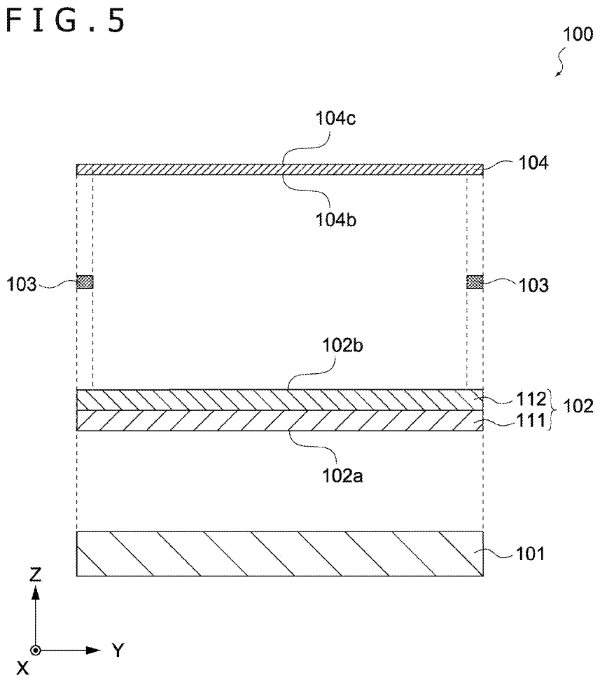

FIG. 1 is a side view of a display device 100 according to an embodiment of the present invention. FIG. 2 is a plan view of the display device 100 seen from the front side, and FIG. 3 is a plan view of the display device 100 seen from the back side. FIG. 4 is a cross-sectional view of the display device 100, taken along line A-A in FIGS. 2 and 3. FIG. 5 is an exploded schematic diagram of the display device 100 illustrated in FIG. 4.

As illustrated in these figures, the display device 100 includes a display panel 101, a touch panel 102, a spacer 103, a tactile panel 104, and a piezoelectric actuator 105. As illustrated in FIGS. 2 and 3, the display device 100 has a flat plate shape, and has a rectangular shape when viewed from a direction perpendicular to the thickness direction. In each figure of the present disclosure, it is assumed that the longitudinal direction of the display device 100 is an X direction, the lateral direction is a Y direction, and the thickness direction is a Z direction.

The display panel 101 is a panel that displays images, and is a display panel that uses liquid crystal or organic EL (electro-luminescence), for example. The configuration of the display panel 101 is not particularly limited to any kind, and may be a display having a general configuration.

The touch panel 102 is disposed on the display panel 101 and detects a touch on the display device 100 by a user's finger, for example. As illustrated in FIG. 5, the touch panel 102 includes a touch panel main body 111 and a cover glass 112. The touch panel main body 111 includes an array of touch sensors. The touch sensor is preferably of a capacitive type. The cover glass 112 is bonded to the touch panel main body 111 and protects the touch panel main body 111.

Hereinafter, among the principal surfaces of the touch panel 102, the principal surface on the display panel 101 side is referred to as a first principal surface 102a, and the principal surface on the side opposite to the first principal surface 102a is referred to as a second principal surface 102b. The principal surface of the touch panel 102 on the touch panel main body 111 side is the first principal surface 102a, and the principal surface on the cover glass 112 side is the second principal surface 102b.

The spacer 103 is disposed on the second principal surface 102b of the touch panel 102 to separate the touch panel 102 and the tactile panel 104 from each other. The spacers 103 each have a belt-like shape as illustrated in FIGS. 2 and 3, and are arranged along the long sides of the display device 100, respectively. The spacer 103 preferably includes a material with an elastic modulus of 1.0×10⁶ to 6.0×10⁶ Pa, and to be specific, preferably includes urethane rubber, polyurethane, or PET (polyethylene terephthalate), for example.

The tactile panel 104 is placed on the spacer 103 to present a tactile sensation to the user. As illustrated in FIG. 1, the tactile panel 104 has long sides longer than those of other members such as the touch panel 102, and has a portion 104a protruding from the other members. The piezoelectric actuator 105 is connected to the portion 104a, and vibration is generated by the piezoelectric actuator 105. The tactile panel 104 includes a light-transmissive material such as glass or resin. It is assumed that the surface of the tactile panel 104 on the touch panel 102 side is a third principal surface 104b and that the principal surface on the side opposite to the third principal surface 104b is a fourth principal surface 104c.

The tactile panel 104 is separated from the touch panel 102 by the spacer 103, and the third principal surface 104b faces the second principal surface 102b of the touch panel 102 with a gap therebetween. Hereinafter, the gap between the second principal surface 102b and the third principal surface 104b will be referred to as a gap R.

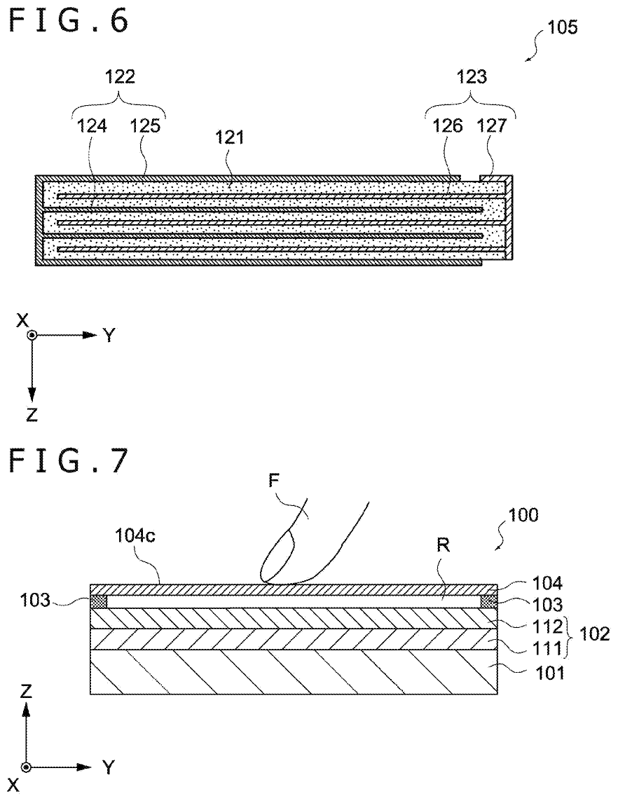

The piezoelectric actuator 105 is bonded to the tactile panel 104 and generates vibration. As illustrated in FIG. 1, the piezoelectric actuator 105 is bonded to the third principal surface 104b at the portion 104a of the tactile panel 104. FIG. 6 is a cross-sectional view of the piezoelectric actuator 105. As illustrated in FIG. 6, the piezoelectric actuator 105 includes a piezoelectric body 121, a first electrode 122, and a second electrode 123. The piezoelectric body 121 includes a piezoelectric material such as PZT (lead zirconate titanate).

The first electrode 122 includes first inner electrodes 124 and a first outer electrode 125. The first inner electrodes 124 include a conductive material, and a plurality of layers are provided in the piezoelectric body 121. The first outer electrode 125 includes a conductive material and is connected to the first inner electrodes 124. The second electrode 123 includes second inner electrodes 126 and a second outer electrode 127. The second inner electrodes 126 include a conductive material, and a plurality of layers are provided in the piezoelectric body 121. The second outer electrode 127 includes a conductive material and is connected to the second inner electrodes 126.

As illustrated in FIG. 5, the first inner electrodes 124 and the second inner electrodes 126 are arranged alternately and face each other with the piezoelectric body 121 therebetween. Note that each number of layers of the first inner electrodes 124 and the second inner electrodes 126 is not limited to three. As illustrated in FIGS. 2 and 3, a first wiring 128 is connected to the first electrode 122, and a second wiring 129 is connected to the second electrode 123. The first wiring 128 and the second wiring 129 are connected to an unillustrated drive unit, and transmit a drive signal output from the drive unit, to the first electrode 122 and the second electrode 123.

When a voltage is applied between the first electrode 122 and the second electrode 123 by this drive signal, the shape of the piezoelectric body 121 is changed due to the inverse piezoelectric effect, and vibration is generated. Here, in the display device 100, the control unit supplies an ultrasonic drive signal to the piezoelectric actuator 105, so that the piezoelectric actuator 105 can be caused to generate vibration in an ultrasonic band (20 kHz or higher). Further, by the control unit supplying a low frequency drive signal to the piezoelectric actuator 105, the piezoelectric actuator 105 can be caused to generate vibration in a low frequency band (300 Hz or less).

Note that the piezoelectric actuator 105 may have a laminated structure in which the first electrodes 122 and the second electrodes 123 are alternately stacked with the piezoelectric body 121 therebetween, as illustrated in FIG. 5, or may have another structure.

### [Operation of Display Device]

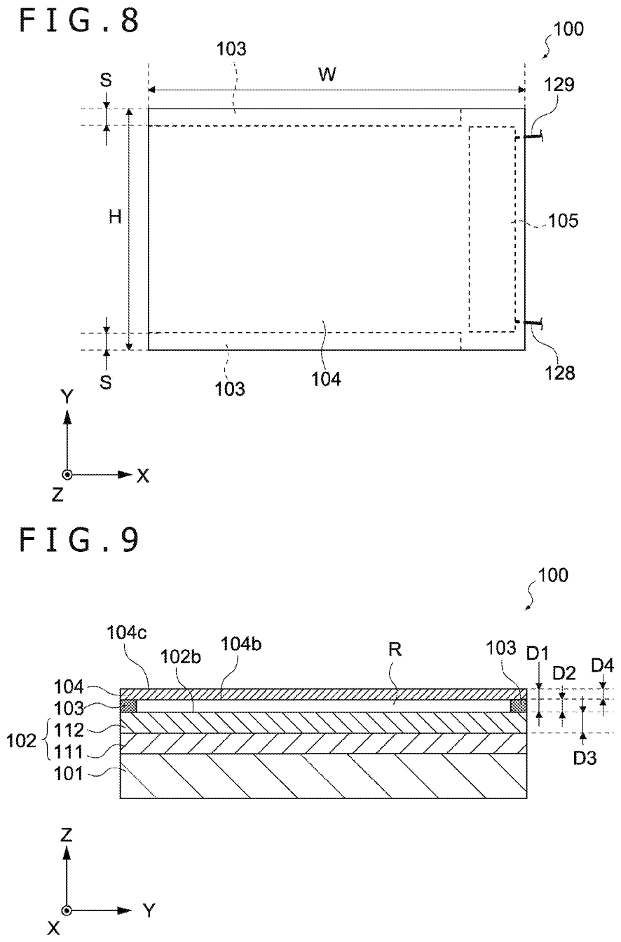

The operation of the display device 100 will be described. FIG. 7 is a schematic diagram illustrating the operation of the display device 100. As illustrated in FIG. 7, when the piezoelectric actuator 105 (see FIG. 1) vibrates with a user's finger F in contact with the fourth principal surface 104c of the tactile panel 104, the vibration is transmitted to the tactile panel 104, and the tactile panel 104 vibrates. This allows the finger F to get a tactile sensation. The piezoelectric actuator 105 may be vibrated in an ultrasonic band or may be vibrated in a low frequency band.

Here, since the tactile panel 104 and the touch panel 102 are separated from each other by the gap R, vibration of the tactile panel 104 is prevented from being attenuated by the touch panel 102. Further, the touch panel 102 detects the contact of the finger F with the tactile panel 104. Moreover, the image displayed by the display panel 101 is visible through the touch panel 102 and the tactile panel 104.

### [Size of Each Portion]

The size of each portion of the display device 100 will be described. FIGS. 8 and 9 are schematic diagrams illustrating the sizes of each part of the display device 100. As illustrated in FIG. 9, the thickness from the second principal surface 102b to the fourth principal surface 104c, that is, the total thickness of the gap R and the tactile panel 104, is defined as a first thickness D1. Further, the thickness from the second principal surface 102b to the third principal surface 104b, that is, the thickness of the gap R, is defined as a second thickness D2. Moreover, the thickness of the cover glass 112 is defined as a third thickness D3, and the thickness of the tactile panel 104 is defined as a fourth thickness D4.

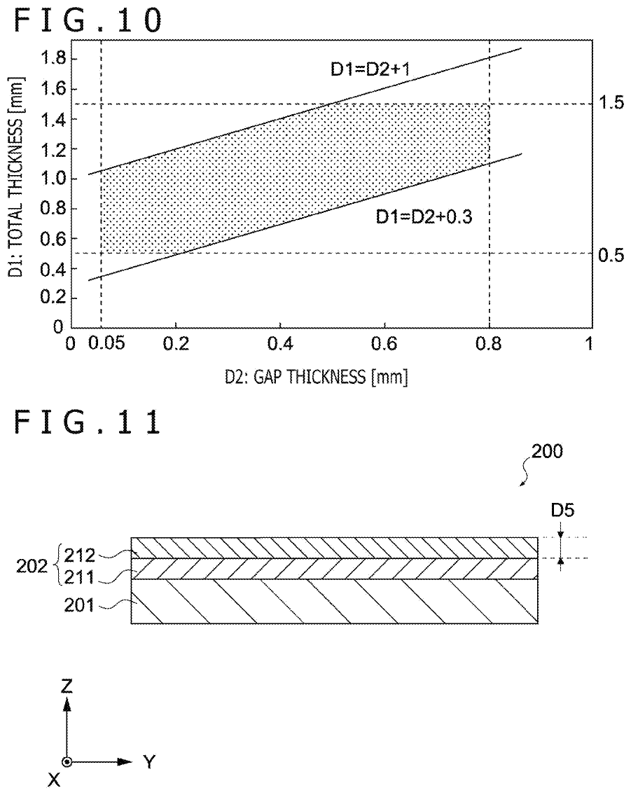

FIG. 10 is a graph illustrating a preferable range of the first thickness D1 and the second thickness D2, and the preferable range of the first thickness D1 and the second thickness D2 is illustrated by shading. As illustrated in FIG. 10, the second thickness D2 is preferably 0.05 to 0.8 mm. In addition, in FIG. 10, the first thickness D1 obtained by adding 0.3 mm to the second thickness D2 is illustrated as “D1=D2+0.3,” and the first thickness D1 obtained by adding 1 mm to the second thickness D2 is illustrated as “D1=D2+1.” The first thickness D1 is preferably 0.5 to 1.5 mm, and is greater than or equal to the thickness obtained by adding 0.3 mm to the second thickness D2 (D2+0.3) and is less than or equal to the thickness obtained by adding 1 mm to the second thickness D2 (D2+1), as illustrated by the shaded area in FIG. 10.

This is because, in a case where the first thickness D1 is less than 0.5 mm or less than the thickness obtained by adding 0.3 mm to the second thickness D2 (D2+0.3), when vibrating, the tactile panel 104 comes in contact with the touch panel 102, and the vibration is attenuated. Further, this is because, in a case where the first thickness D1 exceeds 1.5 mm or exceeds the thickness obtained by adding 1 mm to the second thickness D2 (D2+1), vibration of the tactile panel 104 is affected, and touch detection by the touch panel 102 becomes difficult.

The third thickness D3 (see FIG. 9) is preferably 0 to 0.5 mm, and the fourth thickness D4 is preferably 0.3 to 1.0 mm. For comparison, FIG. 11 is a cross-sectional view illustrating a display device 200 without a tactile panel. As illustrated in FIG. 11, the display device 200 includes a display panel 201 and a touch panel 202, and the touch panel 202 includes a touch panel main body 211 and a cover glass 212. As illustrated in FIG. 11, the thickness of the cover glass 212 is defined as a fifth thickness D5. The fifth thickness D5 needs to be 0.2 to 1.0 mm in order to ensure the strength of the display device 200.

On the other hand, since the display device 100 (see FIG. 9) includes the tactile panel 104, the fourth thickness D4, which is the thickness of the tactile panel 104, and the second thickness D2, which is the thickness of the gap R, are added on the touch panel 102, so that the strength of the display device 100 is improved. Therefore, the third thickness D3, which is the thickness of the cover glass 112, can be reduced to 0 to 0.5 mm. Further, in order to generate a low-frequency drive force feedback function by use of the piezoelectric actuator 105, the fourth thickness D4 is preferably set to 0.3 to 1.0 mm to prevent low-frequency vibration from being attenuated during transmission through the tactile panel 104.

As illustrated in FIG. 8, regarding the planar shape of the tactile panel 104, when the width along the long side of the tactile panel 104 is a width W and the width along the short side of the tactile panel 104 is a width H, a length W is preferably 1 time to 2.5 times larger than a length H. Further, the total of widths S of the spacers 103 is preferably 0.4% to 10% of the width H, the width H is preferably 50 to 250 mm, and the width S is preferably 1 to 5 mm.

### [Effects of Display Device]

In the display device 100, the tactile panel 104 is disposed on the touch panel 102 with the gap R therebetween. Therefore, even if ultrasonic vibration is generated in the tactile panel 104 by the piezoelectric actuator 105, the tactile panel 104 does not come into contact with the touch panel 102, and the vibration is not inhibited by contact. Further, since the tactile panel 104 and the gap R prevent external physical shocks from being transmitted to the touch panel 102 and the display panel 101, the third thickness D3 (see FIG. 9), which is the thickness of the cover glass 112, can be reduced or eliminated. As a result, even if a tactile presentation mechanism is added, the overall thickness of the display device 100 can be suppressed.

Further, by setting the fourth thickness D4, which is the thickness of the tactile panel 104, to be 0.3 to 1.0 mm, the low frequency vibration of the tactile panel 104 can be prevented from being attenuated. Accordingly, as illustrated in FIG. 1, a force feedback function can be achieved by generating low frequency vibration in the piezoelectric actuator 105 disposed near the end of the tactile panel 104. Therefore, in the display device 100, the tactile function by the ultrasonic vibration of the tactile panel 104 and the force feedback function by the low frequency vibration of the tactile panel 104 can be achieved by one piezoelectric actuator 105.

### Modification Example

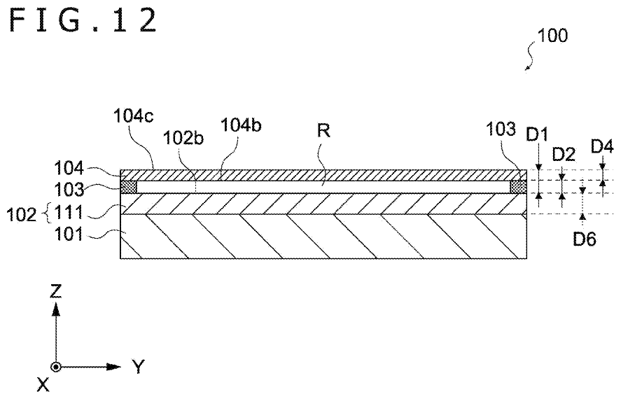

FIG. 12 is a schematic diagram of the display device 100 according to a modification example of the present invention. As illustrated in FIG. 12, the touch panel 102 may include only the touch panel main body 111 without including the cover glass 112 (see FIG. 1). In this structure, the touch panel main body 111 also serves as a cover glass. As illustrated in FIG. 12, when the thickness of the touch panel main body 111 is a sixth thickness D6, the sixth thickness D6 can be 0.2 to 0.5 mm. Also in this structure, the fourth thickness D4, which is the thickness of the tactile panel 104, and the second thickness D2, which is the thickness of the gap R, are added on the touch panel 102, so that the strength of the display device 100 is improved, and therefore, the sixth thickness D6 can be reduced to 0.2 to 0.5 mm.

### REFERENCE SIGNS LIST

100: Display device
101: Display panel
102: Touch panel
102a: First principal surface
102b: Second principal surface
103: Spacer
104: Tactile panel
104b: Third principal surface
104c: Fourth principal surface
105: Piezoelectric actuator
111: Touch panel main body
112: Cover glass

1-7. (canceled)

2. A display device, comprising:
a display panel;
a touch panel that is disposed on the display panel and has a first principal surface facing the display panel and a second principal surface on a side opposite to the first principal surface;
a spacer disposed on the second principal surface;
a tactile panel that is disposed on the spacer and has a third principal surface facing the second principal surface with a gap between the third and second principal surfaces and a fourth principal surface on a side opposite to the third principal surface; and
a piezoelectric actuator that is disposed on the third principal surface and generates vibration, wherein,
when a thickness from the second principal surface to the fourth principal surface is a first thickness and a thickness from the second principal surface to the third principal surface is a second thickness, the first thickness is 0.5 to 1.5 mm, is equal to or greater than a thickness obtained by adding 0.3 mm to the second thickness, and is equal to or less than a thickness obtained by adding 1 mm to the second thickness.

3. The display device according to claim 2, further comprising:
a drive unit that supplies the piezoelectric actuator with an ultrasonic drive signal that causes the piezoelectric actuator to generate vibration in an ultrasonic band and a low frequency drive signal that causes the piezoelectric actuator to generate vibration in a low frequency band.

4. The display device according to claim 2, wherein
the spacer includes a material having an elastic modulus of 1.0×106 to 6.0×106 Pa.

5. The display device according to claim 2, wherein
the second thickness is 0.05 to 0.8 mm.

6. The display device according to claim 2, wherein
the tactile panel has a rectangular shape having a width of a long side that is 1 time to 2.5 times larger than a width of a short side.

7. The display device according to claim 2, wherein
the tactile panel includes resin or glass.

8. An electronic device, comprising:
a display panel;
a touch panel that is disposed on the display panel and has a first principal surface facing the display panel and a second principal surface on a side opposite to the first principal surface;
a spacer disposed on the second principal surface;
a tactile panel that is disposed on the spacer and has a third principal surface facing the second principal surface with a gap between the third and second principal surfaces and a fourth principal surface on a side opposite to the third principal surface; and
a piezoelectric actuator that is disposed on the third principal surface and generates vibration, wherein,
when a thickness from the second principal surface to the fourth principal surface is a first thickness and a thickness from the second principal surface to the third principal surface is a second thickness, the first thickness is 0.5 to 1.5 mm, is equal to or greater than a thickness obtained by adding 0.3 mm to the second thickness, and is equal to or less than a thickness obtained by adding 1 mm to the second thickness.
